(19) United States
(12) Patent Application Publication
(10) Pub. No.: US 2006/0068545 A1
(43) Pub. Date: Mar. 30, 2006

(54) Fabricating transistor structures for DRAM semiconductor components

(76) Inventor: Matthias Goldbach, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/238,113

(22) Filed: Sep. 29, 2005

(30) Foreign Application Priority Data
Sep. 30, 2004 (DE) 10 2004047 751.5

(51) Int. Cl. H01L 21/8242; H01L 21/20

(52) U.S. Cl. 438/256; 438/396; 438/514

(57) ABSTRACT

A method for fabricating transistor structures for DRAM semiconductor components includes forming gate conductor structures in a cell array of a DRAM semiconductor component and covering the structures with a spacer liner. The gate conductor structures lie on a silicon semiconductor substrate. A masked spacer etch produces a spacer mask with horizontal sections and vertical spacer structures from the spacer liner for aligning implantation steps and for self-aligned formation of silicide structures at the surface of the semiconductor substrate. A CB contact implantation step is provided prior to the filling of trenches between the gate conductor structures with dielectric silicate glass fillings, and this obviates the need for an isolated high-temperature activation anneal for the CB contact implantation as well as reducing the thermal stresses on regions of the semiconductor substrate which have already been doped. A reflow heating step for partially melting the silicate glass is controlled as a final furnace anneal for annealing lattice defects in the semiconductor substrate. The contact resistance of a bit contact structure is lowered, while at the same time the thermal stresses are reduced.

### CROSS REFERENCE TO RELATED APPLICATIONS

This application claims priority under 35 USC §119 to German Application No. DE 10 2004 047 751.5, filed on Sep. 30, 2004, and titled “Method for Fabricating Transistor Structures for DRAM Semiconductor Components,” the entire contents of which are hereby incorporated by reference.

### FIELD OF THE INVENTION

The invention relates to fabricating transistor structures for cell arrays of DRAM semiconductor components and to fabricating transistor structures for DRAM semiconductor components.

### BACKGROUND

DRAM semiconductor components include a cell array in which DRAM memory cells for storing an electric charge that characterizes a data content of the respective memory cell are arranged in a high density and a supporting circuit region or support region including electronic circuits for addressing individual memory cells and for signal conditioning.

The DRAM memory cells each include a storage capacitor for storing the electric charge and a select transistor for temporarily connecting a storage electrode of the storage capacitor to a data line. The storage capacitors are formed either as trench capacitors oriented along trenches which have been introduced into a semiconductor substrate from a substrate surface, or as stack capacitors in an insulator layer above the substrate surface.

The select transistors are provided as field-effect transistors with an active area including two source/drain regions and a channel region which spaces the two source/drain regions apart from one another, as well as a gate electrode which lies above the channel region and is spaced apart from the channel region by a gate dielectric. A potential at the gate electrode controls the formation of a conductive channel through the channel region between the two source/drain regions and temporarily switches the storage electrode of the respective storage capacitor which is connected to the first source/drain region on to the data or bit line connected to the second source/drain region.

The select transistors of the memory cell array are generally formed as n-channel field-effect transistors. Standard circuits for the support region provide both n-channel and p-channel field-effect transistors.

The source/drain regions are designed as n-doped or p-doped sections of the semiconductor substrate. The formation of the select and support transistors includes forming a gate dielectric on a substrate surface of the semiconductor substrate, depositing gate conductor material, patterning the gate conductor material(s) to form gate conductor structures, with the substrate surface being uncovered in sections in the region of trenches between the gate conductor structures, and implanting dopants to form the source/drain regions next to the gate conductor structures. Contact structures which are connected with a low resistance to the doped regions in the semiconductor substrate and connect these regions to interconnects that are to be provided above the gate conductor structures, are provided between the gate conductor structures.

The properties of the transistors are determined to a considerable degree by the doping profile in the active area. The access times of the memory cells are influenced to a considerable degree by the contact resistance between the source/drain regions and the respective contact structure, and the charge retention (data retention) properties are influenced to a considerable degree by the leakage current of the storage capacitor.

During the ion implantation of a dopant into a monocrystalline semiconductor substrate, for example of boron into monocrystalline silicon, the crystal microstructure of the silicon is disrupted by dislocations or even rendered completely amorphous. Doping atoms which are bound in the region of the dislocations are inactive and make no contribution to charge carrier transport. Therefore, an implantation step is generally followed by a high-temperature activation anneal at temperatures of more than 900 degrees Celsius. The activation anneal recrystallizes regions that have been rendered amorphous, restructures dislocations in the crystal lattice and in the process activates the doping atoms. The activation anneal follows the implantation generally in each case before the next process step, which exceeds a temperature of 600 degrees Celsius, in order to prevent the doping atoms from diffusing out into the semiconductor substrate.

Depending on the temperature and duration of each successive heating step involved in processing, the doping atoms diffuse in the direction of decreasing concentration, so that the maximum dopant concentration and the concentration gradient decrease. For feature sizes of smaller than 100 nanometers, a drop in the dopant concentration by an order of magnitude within 15 nanometers generally cannot be tolerated. It is aimed for the dopant concentration to decrease by an order of magnitude within no more than 5 nanometers. Each heating step adversely affects the dopant profile of regions that have already been implanted, depending on the maximum temperature and duration of the heating step.

The maximum temperature and the holding time at the maximum temperature of the activation anneal are crucial factors in the effect of this activation anneal. The duration of the activation anneal can remain limited to a few seconds. Accordingly, the activation anneals are controlled with fast temperature gradients.

As the temperature rises, so does the proportion of atoms outside the crystal lattice of the semiconductor substrate. This state is frozen during rapid cooling, and the crystal lattice has more defects and vacancies after cooling than would result from the equilibrium at the cooling temperature. Vacancies or point defects of this type in the crystal lattice promote leakage current mechanisms, which reduce the data retention time of the DRAM memory cell.

Therefore, what is known as a final furnace anneal with a maximum temperature of approximately 800 degrees Celsius and a cooling rate of at most 1 degree Celsius per second is required to anneal lattice vacancies and defects in the monocrystalline semiconductor substrate. The cooling rate is then sufficiently slow to ensure that the lattice vacancies and defects are filled up again so as to match the equilibrium state at the respective temperature.

In the case of DRAM semiconductor components, a dielectric filling of a silicate glass, generally borophosphosilicate glass (BPSG), is provided between the gate electrodes by ion implantation and subsequent activation anneal after the formation of doped source/drain regions. The application of silicate glass includes a final partial melting (BPSG reflow) at temperatures of at least approximately 770 degrees Celsius.

The silicate glass is opened up in the memory cell array above the second source/drain regions. As the production sequence continues, contact structures are introduced into the contact openings formed. Contact implantations (CB implantation in the cell array, CS implantation in the support region) are carried out to reduce the contact resistance between the second source/drain regions and the respective contact structure, and these contact implantations are in turn followed by a further activation anneal.

Furthermore, the self-aligned formation of metal silicide (saliciding, self-aligned siliciding) is also known to reduce the contact resistance. For this purpose, those sections of the semiconductor substrate which are intended to be silicided are uncovered and a metal is applied by sputtering. If the metal provided is cobalt, in a first, rapid thermal step, a cobalt silicide of a phase with low conductivity is formed at the locations at which the cobalt rests directly on the silicon. The unreacted metal is removed, and the low-conductivity phase is converted into a high-conductivity phase in a second thermal step. Cobalt silicide is stable up to approximately 850 degrees Celsius. If cobalt silicide is exposed to temperatures of more than 850 degrees Celsius, cobalt silicide agglomerates are formed, the boundary surfaces of which constitute leakage current paths.

Another metal provided for the formation of silicide is titanium. When using smaller dimensions, titanium silicide forms comparatively large TiSi grains. The coarse grain structure results in a high sheet resistance.

The combination of the abovementioned process steps leads to high thermal stresses, made up of the activation anneal for the source/drain implantations, the heating steps involved in the siliciding process, the BPSG reflow, the activation anneal of the contact implantations, and the final furnace anneal.

The thermal budget which is permissible for the doped regions of a transistor structure depends on the absolute dimensions of the transistor structure and in particular on the distance between the two source/drain regions, corresponding to a gate width of the transistor structures. For transistor structures with gate widths of less than 100 nanometers, the method described generally exceeds the thermal budget which is permissible for a suitable doping profile.

### SUMMARY OF THE INVENTION

An object of the invention is to provide a method for fabricating transistor structures for a cell array or for DRAM semiconductor components that allows the contact resistances in the cell array to be reduced without increasing the thermal stresses on implanted structures.

This and other objects are achieved in accordance with the present invention by providing a method for fabricating transistor structures for cell arrays of DRAM semiconductor components. The method comprises providing gate conductor structures that are spaced apart from each other on a substrate surface of a semiconductor substrate in a cell array such that, between at least two gate conductor structures, first sections of the semiconductor substrate that are to be connected with a CB contact structure and second sections of the semiconductor substrate that are to be connected with a storage capacitor are uncovered in the cell array. A spacer mask is patterned over portions of the substrate including vertical sections along vertical side walls of the gate conductor structures and horizontal sections above the second sections, where the first sections remain uncovered. The method further comprises performing CB implantation of dopants so as to form BC contact regions in the first sections of the semiconductor substrate, activating the dopant of the CB implantation via a high-temperature activation anneal, and depositing silicate glass over portions of the substrate including the gate conductor structures. The deposited silicate glass is partially melted in a reflow heating step, where the reflow heating step is controlled to also facilitate a final furnace anneal that slow anneals lattice defects in the semiconductor substrate.

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIGS. 1 to 8 depict diagrammatic and partial cross-sectional views of transistor structures that show various stages of processing in accordance with a first exemplary embodiment of the method according to the invention.

FIG. 9 depicts a diagrammatic and partial cross-sectional view of a transistor structure for DRAM semiconductor components in accordance with a second exemplary embodiment of the invention.

### DETAILED DESCRIPTION

In accordance with the present invention, a method for fabricating transistor structures for DRAM semiconductor components includes providing gate conductor structures that are spaced apart from one another on a substrate surface of a semiconductor substrate with a cell array. First sections of the semiconductor substrate that connect to a CB contact structure and second sections of the semiconductor substrate that connect to a storage capacitor are uncovered between the gate conductor structures in the cell array. The storage capacitor can be provided as a trench capacitor or as a stack capacitor.

A spacer mask with vertical and horizontal sections is patterned over the relief on the semiconductor substrate formed from the gate conductor structures. The vertical sections cover the vertical side walls of the gate conductor structures. The horizontal sections of the spacer mask cover the second sections of the semiconductor substrate, with the first sections remaining uncovered.

During a CB implantation, a dopant is introduced into the first sections of the semiconductor substrate in order to form doped BC contact regions. A significant proportion of the dopant is inactive following the CB implantation. The dopant is activated by a high-temperature activation anneal.

Subsequently, a silicate glass, for example a silicate glass doped with boron and phosphorus (borophosphosilicate glass, BPSG), is applied. The deposited silicate glass is partially melted in a reflow heating step.

The sequence of process steps according to the invention allows the reflow heating step to be controlled in an advantageous way using the process parameters of a final furnace anneal for slow annealing of lattice defects in the semiconductor substrate, so that depending on how the reflow heating step is considered, the final furnace anneal is eliminated or the final furnace anneal and the reflow heating step are combined into a single heating step.

In standard methods which provide for a CB contact implantation, to avoid siliciding in the cell array, the cell array is covered with silicate glass, the silicate glass is subsequently opened up above the first sections, and then the CB contact implantation is carried out. The final furnace anneal can then be deferred in the process flow until a time at which the processing of the silicate glass including the reflow heating step has already ended.

According to the invention, the thermal stressing of the doped structures in the semiconductor substrate is considerably reduced by the elimination of the reflow heating step.

Furthermore, it is advantageously possible for the first sections of the semiconductor substrate to be silicided following the final high-temperature activation anneal.

The siliciding takes place in a self-aligned manner through the spacer mask on top at the first sections of the semiconductor substrate that are intended to be silicided. The contact resistance of the structures within the semiconductor substrate is advantageously reduced.

The siliciding preferably includes the deposition of cobalt, if necessary of a titanium and/or titanium nitride cap, a first rapid heating step for self-aligned formation of a low-conductivity phase of cobalt silicide, if appropriate removal of the cap, removal of the unreacted cobalt and a second rapid heating step for phase transformation of the cobalt silicide into a high-conductivity phase.

Since the siliciding can advantageously be provided after the last activation anneal, unlike in conventional concepts, the cobalt silicide does not undergo an activation anneal and the need for the cobalt silicide to be protected from temperatures over 800 degrees Celsius, for example by a nitrogen ion implantation, is advantageously eliminated.

The step of providing a CB implantation in the cell array of a DRAM semiconductor component by a spacer mask prior to the deposition of the silicate glass, which is crucial to the invention, advantageously leads to a reduction in the thermal stressing even without any further measures, due to the elimination of an implantation anneal, at the level of a DRAM semiconductor component which, in addition to the cell array including the memory cells, also includes a support region with supporting circuits for addressing and signal conditioning purposes.

A cell array including DRAM memory cells, each having a storage capacitor and a select transistor, and a support region having electronic circuits for addressing and conditioning data signals, are provided in a semiconductor substrate of a DRAM semiconductor component. Gate conductor structures that are spaced apart from one another in the customary way are provided on a substrate surface of the semiconductor substrate.

As above, a spacer mask including vertical and horizontal sections is patterned over the relief on the semiconductor substrate formed on the gate conductor structures. The vertical side walls of the gate conductor structures in the cell array and in the support region are covered by the vertical sections. The horizontal sections of the spacer mask cover the second sections of the semiconductor substrate in the cell array. The semiconductor substrate remains uncovered in the support region at least in the region of the source/drain regions of the support transistors and in the cell array in the region of the first sections of the semiconductor substrate.

During support implantations and a CB implantation, dopants are introduced into the semiconductor substrate in order to form source/drain regions of the support transistors and doped BC contact regions in the cell array.

The activation of the support implantations and of the contact implantation in the cell array advantageously takes place in the same step. The thermal stressing of the support implantations is reduced by the thermal budget of the activation anneal for activating the CB contact implantation compared to the conventional method described above.

It is particularly advantageous for the semiconductor substrate to be silicided after the activation anneal has been carried out, the siliciding being carried out in self-aligned fashion through the gate conductor structures on top at the contact sections of the semiconductor substrate intended for siliciding. The contact resistance of the structures within the semiconductor substrate is advantageously reduced.

The siliciding, as above, preferably includes the deposition of cobalt, if appropriate of a titanium and/or titanium nitride cap, a first rapid thermal step for the self-aligned formation of a low-conductivity phase of cobalt silicide, if appropriate the removal of the cap, the removal of unreacted cobalt and a second rapid thermal step for phase transformation of the cobalt silicide into a high-conductivity phase.

In applications where providing the silicate glass fillings also includes partial melting of a deposited silicate glass in a reflow heating step, it is advantageously possible, as described above, for the reflow heating step to be carried out as a final furnace anneal. The dopant profiles or dopant concentrations in the active areas of the transistor structures can advantageously be carried out with higher gradients than conventional methods. The transistor structures can be realized with improved properties in smaller dimensions.

The reflow heating step is preferably controlled with a maximum temperature of between 770 and 850 degrees Celsius, a holding time at the maximum temperature of at least 1 minute and a cooling rate of at most 1 degree Celsius per second.

It is preferable to introduce polysilicon plugs between the gate conductor structures after the siliciding step and before the step of providing the silicate glass fillings, by depositing a polysilicon layer and then photolithographically patterning the polysilicon layer above the first sections of the semiconductor substrate. After the application and planarization of the silicate glass fillings, the polysilicon plugs are removed selectively with respect to the silicate glass. Metal-containing CB contact structures are introduced into the contact openings that have formed.

Advantageous simultaneous introduction of the CB contact structures with gate contact structures and source/drain contact structures in the support region is possible without the need for a photolithographic patterning step in the cell array.

A barrier layer (middle-of-line liner, MOL liner), which is preferably applied after the siliciding or after the polysilicon plugs and before the silicate glass fillings, prevents the outdiffusion of the dopants of the silicate glass.

The high-temperature activation anneal is preferably controlled so as to have a duration of less than 10 seconds at a maximum temperature of at least 900 degrees Celsius and with a cooling rate faster than 30 degrees Celsius per second.

To pattern the spacer mask, first of all a dielectric, conformal spacer liner, preferably of silicon oxide, is applied. A photoresist material is deposited on the spacer liner. The photoresist material is patterned in a photolithographic step so as to produce a resist mask. The resist mask is opened up above the first sections of the semiconductor substrate in the cell array and above the source/drain regions of the support transistors in the support region. The spacer liner is anisotropically etched back with the resist mask on top of it, with the spacer mask being produced from the spacer liner.

The horizontal sections of the spacer mask are preferably removed after the siliciding operation, so that the formation of steps at the ends of the horizontal sections is advantageously avoided.

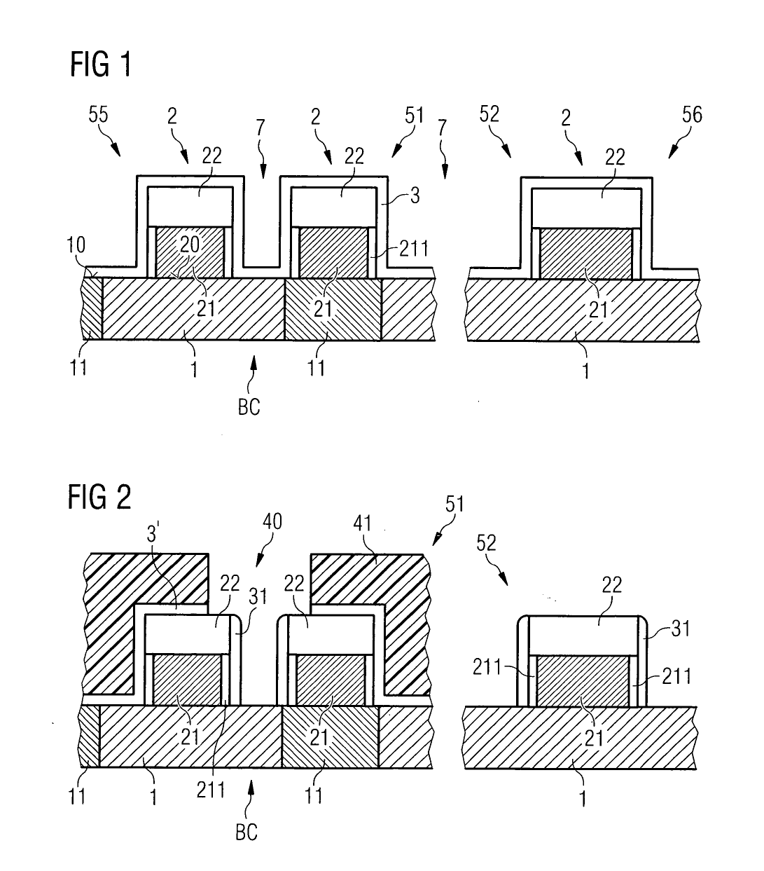

Exemplary embodiments of the present invention are now described with reference to FIGS. 1-9.

Referring to FIG. 1, trenches are introduced into a semiconductor substrate 1 from a substrate surface 10 in the region of a cell array 51 of a semiconductor substrate 1 of a DRAM semiconductor component, and trench capacitors 11 are formed oriented at the trenches.

A gate dielectric layer is formed on the substrate surface 10 between the trench capacitors 11. A gate conductor layer stack, which includes at least a gate conductor layer 21 and an insulator layer 22, is applied to the gate dielectric layer. The gate conductor layer stack is patterned. In the process, gate conductor structures, which are spaced apart from one another by trenches 7 and are spaced apart from the semiconductor substrate 1 by in each case a gate dielectric 20, are produced from the gate conductor layer stack. In the cell array 51, the gate conductor structures 2 are formed in strips and arranged parallel to one another. At the vertical side walls of the gate conductor structures 2, the gate conductor layers 21 are oxidized, producing side wall oxides 211. A gate conductor structure 2 forms a plurality of successive gate electrodes of a plurality of transistor structures.

A conformal spacer liner 3 of silicon oxide is deposited, covering the relief formed from the semiconductor substrate 1 and the gate conductor structures 2 on top of it.

Gate conductor structures 2 covered by the spacer liner 3 in the region of the cell array 51 and of the support region 52 are illustrated in FIG. 1. A first section or bit line contact section BC of the semiconductor substrate 1 is defined between the two gate conductor structures 2 of the cell array 51. In the bit line contact section BC, a source/drain region, formed in the semiconductor substrate 1, of a select transistor is in a subsequent process sequence connected to a data or bit line that is to be provided above the gate conductor structures 2.

Prior to the application of the spacer liner 3, implantation steps, for example those used to form source/drain regions in the cell array 51, are carried out.

A photoresist is applied to the spacer liner 3 and opened up in a photolithographic step above the bit line contact sections BC and above those sections of the semiconductor substrate 1 in the support region 52 in which further implantations are to be carried out. The patterned photoresist forms a resist mask 41, with which an isotropic spacer etch of the spacer liner 3 is carried out. The result of the masked spacer etch is illustrated in FIG. 2.

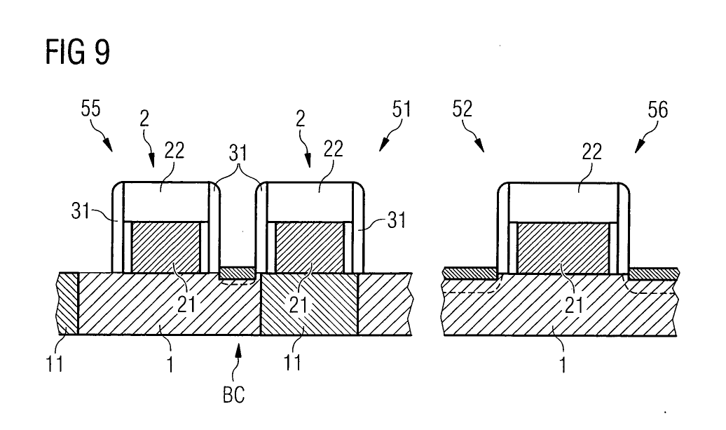

The resist mask 41 is opened up in the region of the cell array 51 above the bit line contact sections BC. The resist mask 41 is absent in the support region 52 in the region of those sections of the semiconductor substrate 1 which are intended for further implantation. Horizontal sections of the spacer liner 3 have been removed in the region of a first CB contact opening 40, and spacer structures 31, which cover the vertical sections of the gate conductor structures 2 in the region of the first CB contact openings 40, have been formed from the spacer liner 3. Outside the first CB contact openings 40, residual sections of the spacer liner 3 form a spacer mask 3′. In the cell array 51, the spacer mask 3′ covers horizontal sections of the semiconductor substrate 1 outside the bit line contact sections BC. In an alternative embodiment depicted in FIG. 9, the spacer liner 3 can be configured in such a way so as to form spacer liners 3 along both vertical sides of each conductor structure 2.

In the support region 52, support implantations 53 are carried out to define source/drain regions 72 for transistor structures for supporting circuits, the distances of which from conducting sections of the gate conductor structures 2 are aligned by the spacer structures 31. The support implantations 53 generally include at least one first implantation step for defining regions of a first conductivity type, for example n-doped source/drain regions of n-channel field-effect transistors, and at least one second implantation step for forming doped regions of the second conductivity type, which is the opposite type to the first conductivity type, for example p-doped source/drain regions of p-channel field-effect transistors, as well as further implantations for optimizing the transistor properties.

In the cell array 51, in combination with or following the first or second implantation step in the support region 52, a contact or CB implantation 54 is carried out, active only in the region of the first contact openings 40.

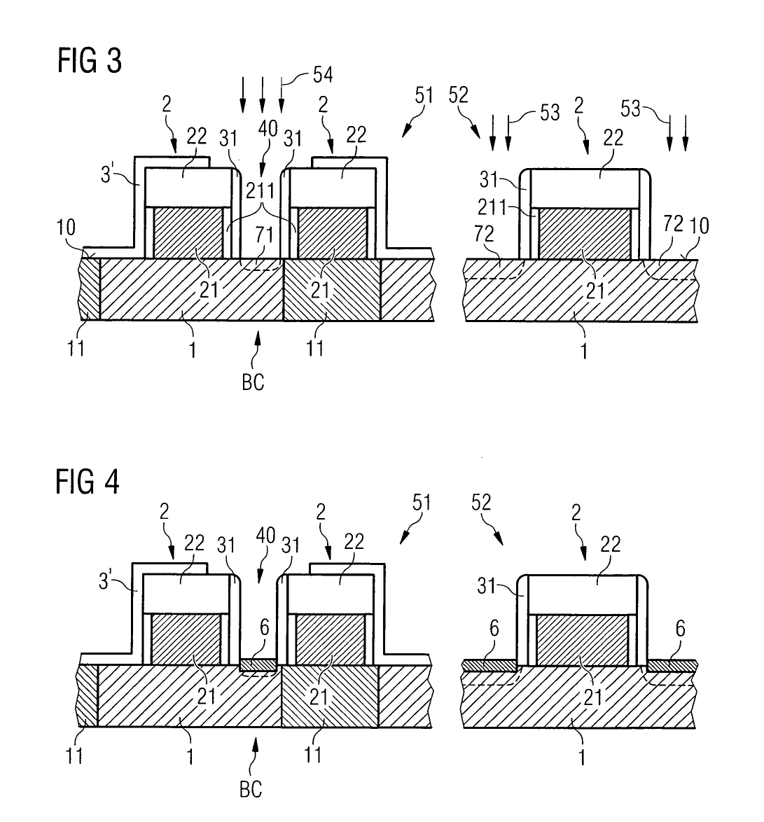

FIG. 3 diagrammatically depicts the implantations 53, 54 in the support region 52 and in the cell array 51, as well as the BC contact regions 71 and source/drain regions 72 formed from the implantations 53, 54. The implantation in the cell array 51 is restricted to the region of the contact openings 40 by the spacer mask 3′. In the region of the contact openings 40, BC contact regions 71 formed from the CB implantation 54 are spaced apart from the gate conductor structures 2 by the spacer structures 31 formed from the spacer liner 3.

Cobalt silicide CoSi₂ is formed in those sections of the semiconductor substrate 1 which are not covered by the spacer mask 3′. Cobalt is deposited by sputtering. In a first rapid thermal step (rapid thermal processing, RTP), a thin film of cobalt silicide is formed at the transition surface from the semiconductor substrate 1 to the cobalt on top of it. The unreacted cobalt is removed in an etching step. In a second rapid thermal step, the cobalt silicide, which is initially in the form of a low-conductivity phase, is transformed into a cobalt silicide of a high-conductivity phase. The siliciding is carried out only where the deposited cobalt rests on silicon.

FIG. 4 illustrates the silicide structures 6 formed from the preceding process step. In the cell array 51, cobalt silicide structures 6 are formed exclusively in the bit line contact sections BC, and are in each case spaced apart from the adjacent gate conductor structures 2 by the spacer structures 31. In the support region 52, cobalt silicide structures 6 are preferentially formed on the source/drain regions 72, at least where contact structures 49 are to be connected to the source/drain regions 72.

Since the final activation anneal was carried out even before the cobalt silicide was formed, the CoSi₂ advantageously maintains a high quality with a low resistivity without any further measures or process steps being required.

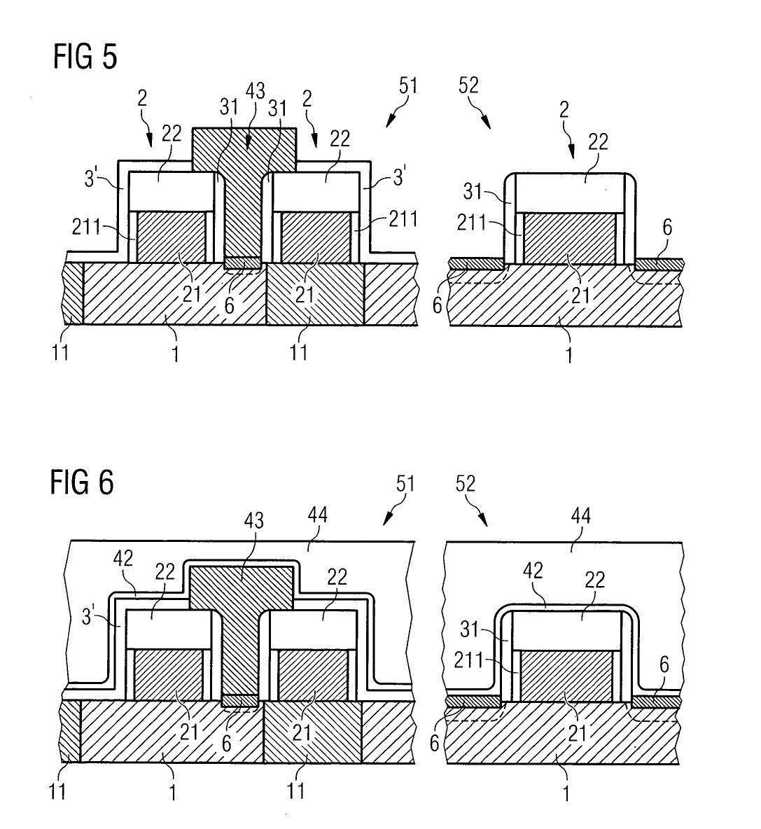

Polysilicon is then deposited and photolithographically patterned. As illustrated in FIG. 5, the patterned polysilicon in the cell array 51 forms polysilicon plugs 43 which fill the contact openings 40 between in each case two adjacent gate conductor structures 2, above the contact sections BC of the semiconductor substrate 1.

A thin conformal barrier layer 42 of silicon nitride is next deposited. The barrier layer 42 covers a relief which has been formed above the semiconductor substrate 1 by the gate conductor structures 2, the spacer structures 31, the spacer mask 3′, the silicide structures 6 and by the polysilicon plugs 43. A doped silicate glass that melts at relatively low temperatures, for example BPSG, is deposited and partially melted (BPSG reflow). The silicate glass 44 fills the relief formed over the substrate surface 10 of the semiconductor substrate 1 completely, as shown in FIG. 6. The surface of the silicate glass 44 is substantially leveled by the partial melting.

The minimum temperature required for the BPSG reflow is, at approximately 770 degrees Celsius, slightly below the usual maximum temperature of the final furnace anneal of 800 degrees Celsius. If the BPSG reflow is carried out at a maximum temperature of 800 degrees Celsius, and if the cooling takes place more slowly than a rate of 1 degree Celsius per second, the BPSG reflow simultaneously acts as a final furnace anneal. The thermal stressing of the doped regions is further significantly reduced.

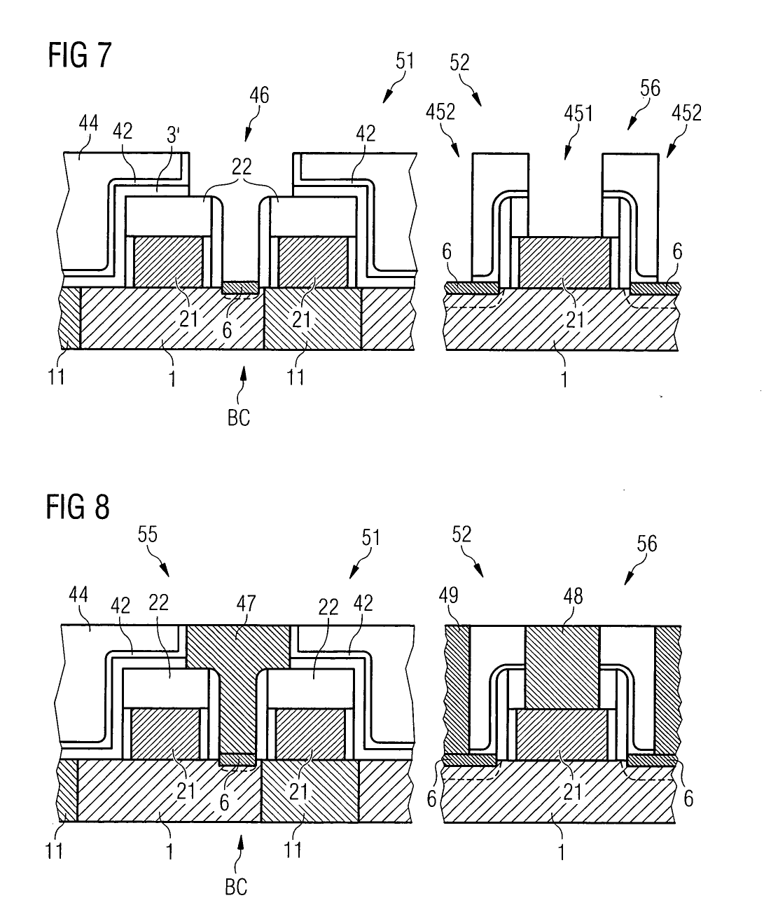

The silicate glass filling 44 is removed down to the top edge of the polysilicon plugs 43, for example by a chemical mechanical polishing (CMP) process. The polysilicon plugs 43 are removed selectively with respect to the silicate glass filling 44. The result is shown in FIG. 7.

As shown in FIG. 7, in the support region 52 gate contact openings 451 are introduced into the gate conductor structures 2, and source/drain contact openings 452 are introduced, by a photolithographic process. The gate contact openings 451 are introduced through the silicate glass filling 44 and the insulator layer 22 as far as the respective gate conductor layer 21.

Adhesion or barrier layers preventing the diffusion of metal atoms are provided, for example, by sputtering on titanium or titanium nitride. Then, tungsten is deposited as contact hole material. In the process, the second CB contact openings 46 in the cell array 51 and the gate openings 451 and CA contact openings 452 in the support region 52 are filled. The tungsten deposited is removed in planar fashion as far as the top of the silicate glass filling 44, for example, by a further CMP step. The contact structures 47, 48 and 49 which have been formed from the tungsten deposition and the CMP step are shown in FIG. 8. The CB contact structures 47 in each case contact-connect BC contact regions 71 of second source/drain regions of select transistors 55 in the cell array 51 with a low resistance via in each case a cobalt silicide structure.

In the support region 52, a GC contact structure 48 contact-connects the gate conductor layer 21 of the support transistor 56. The CA contact structures 49, via cobalt silicide structures 6, contact-connect a first and a second source/drain region 72 of the support transistor 56, which source/drain regions 72 are in each case formed as doped regions in sections of the semiconductor substrate 1.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE DESIGNATIONS

1 Semiconductor substrate
10 Substrate surface
11 Trench capacitor
2 Gate conductor structure
20 Gate dielectric
21 Gate conductor layer
211 Side wall oxide
22 Insulator layer
3 pacer liner
3′ Spacer mask
31 Spacer structure
40 First contact opening
41 Resist mask
42 MOL liner
43 Polysilicon plug
44 Silicate glass filling
45.1 Gate contact opening
45.2 CA contact opening
46 CB contact opening
47 CB contact structure
48 GC contact structure
49 CA contact structure
51 Cell array
52 Support region
53 Support implantations
54 CB implantation
55 Select transistor
56 Support transistor
6 Silicide structure
7 Trench
BC Bit line contact section

What is claimed:

1. A method for fabricating transistor structures for cell arrays of DRAM semiconductor components, comprising:
providing gate conductor structures that are spaced apart from each other on a substrate surface of a semiconductor substrate in a cell array, wherein, between at least two gate conductor structures, first sections of the semiconductor substrate that are to be connected with a CB contact structure and second sections of the semiconductor substrate that are to be connected with a storage capacitor are uncovered in the cell array;
patterning a spacer mask over portions of the substrate including vertical sections along vertical side walls of the gate conductor structures and horizontal sections above the second sections, wherein the first sections remaining uncovered;
performing CB implantation of dopants so as to form BC contact regions in the first sections of the semiconductor substrate;
activating the dopant of the CB implantation via a high-temperature activation anneal;
depositing silicate glass over portions of the substrate including the gate conductor structures; and
partially melting the deposited silicate glass in a reflow heating step, wherein the reflow heating step is controlled to also facilitate a final furnace anneal that slow anneals lattice defects in the semiconductor substrate.

2. The method of claim 1, further comprising:
siliciding the first sections of the semiconductor substrate after the activation anneal.

3. The method of claim 1, wherein the reflow heating step is controlled with a maximum temperature of no greater than 850 degrees Celsius, a holding time at the maximum temperature of at least one minute and a cooling rate of at no greater than 1 degree Celsius per second.

4. The method of claim 1, wherein the high-temperature activation anneal is controlled so as to have a duration of no greater than 10 seconds, a maximum temperature of at least 900 degrees Celsius and a cooling rate faster than 30 degrees Celsius per second.

5. A method for fabricating transistor structures for DRAM semiconductor components, comprising:
providing gate conductor structures that are spaced apart from each other on a substrate surface of a semiconductor substrate in a cell array and a support region, wherein, between at least two gate conductor structures, first sections of the semiconductor substrate that are to be connected with a CB contact structure and second sections of the semiconductor substrate that are to be connected with a storage capacitor are uncovered in the cell array;
patterning a spacer mask over portions of the substrate including vertical sections along vertical side walls of the gate conductor structures and horizontal sections above the second sections, wherein the first sections remaining uncovered;
implanting dopants so as to form support implantations including source/drain regions in the support region and a CB implantation including BC contact regions in the first sections; and
activating the dopants of the support implantations and of the CB implantation in a joint high-temperature activation anneal.

6. The method of claim 5, further comprising:
siliciding uncovered sections of the semiconductor substrate in the support region and the first sections of the semiconductor substrate after the activation anneal.

7. The method of claim 6, further comprising:
providing silicate glass fillings by:
depositing silicate glass over portions of the substrate including the gate conductor structures after the siliciding; and
partially melting the deposited silicate glass in a reflow heating step, wherein the reflow heating step is controlled to also facilitate a final furnace anneal that slow anneals lattice defects in the semiconductor substrate.

8. The method of claim 7, wherein the reflow heating step is controlled with a maximum temperature of no greater than 850 degrees Celsius, a holding time at the maximum temperature of at least one minute and a cooling rate of at no greater than 1 degree Celsius per second.

9. The method of claim 8, further comprising:
introducing polysilicon plugs between adjacent gate conductor structures disposed above the first sections of the cell array after the siliciding step and before providing the silicate glass fillings; and
removing the polysilicon plugs following the reflow heating step.

10. The method of claim 9, further comprising:
applying a conformal barrier layer after introducing the polysilicon plugs and before providing the silicate glass fillings.

11. The method of claim 5, wherein the high-temperature activation anneal is controlled so as to have a duration of no greater than 10 seconds, a maximum temperature of at least 900 degrees Celsius and a cooling rate faster than 30 degrees Celsius per second.

12. The method of claim 5, wherein the patterning of the spacer mask includes:
applying a conformal spacer liner after providing the gate conductor structures;
applying a photoresist material to the spacer liner;
producing a resist mask by removing, via a photolithographic process, the photoresist material above the first sections of the semiconductor substrate in the cell array and from the support region; and
anisotropic etching of the spacer liner in the region of openings in the resist mask, such that the spacer mask is formed from the spacer liner.

13. The method as claimed in claim 12, wherein horizontal sections of the spacer mask are removed after the siliciding step.
